(19) United States
(12) Patent Application Publication
(10) Pub. No.: US 2026/0280486 A1
(43) Pub. Date: Sep. 17, 2026

(54) APPARATUS COMPRISING A PLURALITY OF RESONANT TUNNELING DIODE ELEMENTS, METHOD OF MANUFACTURING SUCH APPARATUS, METHOD OF OPERATING SUCH APPARATUS

(71) Applicant: NOKIA SOLUTIONS AND NETWORKS OY, Espoo (FI)

(72) Inventors: Wolfgang TEMPL, Sersheim (DE); Dirk WIEGNER, Schwaikheim (DE); Stefan WESEMANN, Kornwestheim (DE)

(21) Appl. No.: 19/113,251

(22) PCT Filed: Sep. 29, 2022
(86) PCT No.: PCT/EP2022/077181

§ 371 Date: Mar. 19, 2025

(51) Int. Cl. H03B 7/08

(52) U.S. Cl. CPC H03B 7/08

(57) ABSTRACT

An apparatus comprising a plurality of resonant tunneling diode, RTD, elements and a synchronization signal source configured to provide an optical synchronization signal to the plurality of resonant tunneling diode elements.

### FIELD OF THE DISCLOSURE

Various example embodiments relate to an apparatus comprising a plurality of resonant tunneling diode elements.

Further example embodiments relate to a method of manufacturing an apparatus comprising a plurality of resonant tunneling diode elements.

Further example embodiments relate to a method of operating an apparatus comprising a plurality of resonant tunneling diode elements.

### BACKGROUND

Resonant tunneling diodes comprise a current-voltage characteristic with a negative differential resistance region, so that they can be used to build oscillators.

### SUMMARY

Various embodiments of the disclosure are set out by the independent claims. The exemplary embodiments and features, if any, described in this specification, that do not fall under the scope of the independent claims, are to be interpreted as examples useful for understanding various exemplary embodiments of the disclosure.

Some embodiments relate to an apparatus comprising a plurality of resonant tunneling diode, RTD, elements and a synchronization signal source configured to provide an optical synchronization signal to the plurality of resonant tunneling diode elements. In some exemplary embodiments, this enables to synchronize several ones, for example all, of the plurality of resonant tunneling diode elements, whereby, for example, optically synchronized radio frequency oscillators based on the respective resonant tunneling diode elements may be provided. In other words, in some exemplary embodiments, the plurality of resonant tunneling diode elements are light sensitive, e.g. sensitive at least to the optical synchronization signal, and may thus be optically synchronized using the optical synchronization signal.

Thus, some exemplary embodiments relate to an apparatus comprising a plurality of resonant tunneling diode, RTD, elements and a synchronization signal source configured to provide an optical synchronization signal to the plurality of resonant tunneling diode elements for effecting a phase synchronization of the plurality of resonant tunneling diode elements.

In other words, some exemplary embodiments relate to an apparatus for providing, e.g. generating, radio frequency signals, e.g. using the plurality of resonant tunneling diode elements and the synchronization signal source configured to provide an optical synchronization signal to the plurality of resonant tunneling diode elements, e.g. for effecting a phase synchronization of the plurality of resonant tunneling diode elements.

In some exemplary embodiments, the proposed optical synchronization enables to provide precisely synchronized resonant tunneling diode elements thus e.g. enabling to coherently combine respective output signals of the synchronized resonant tunneling diode elements, wherein, in some exemplary embodiments, e.g. higher signal powers can be attained.

In some exemplary embodiments, each of the plurality of resonant tunneling diode elements is configured to oscillate at a predetermined resonance frequency, wherein, for example, the optical synchronization signal comprises the predetermined resonance frequency.

In some exemplary embodiments, at least some resonant tunneling diode elements of the plurality of resonant tunneling diode elements, e.g. all of the plurality of resonant tunneling diode elements, may comprise one or more (e.g., further) electronic components, e.g. to provide a resonator circuit based on the respective resonant tunneling diode element.

In some exemplary embodiments, the apparatus is configured to effect a phase synchronization of the plurality of resonant tunneling diode elements by means of injection locking of the plurality of resonant tunneling diode elements using the optical synchronization signal.

In some exemplary embodiments, the plurality of resonant tunneling diode elements are arranged in form of an array, wherein the array is at least one of: a) a one-dimensional array, b) a two-dimensional array, c) a three-dimensional array. In some exemplary embodiments, the array may be a uniform array, e.g. uniform linear array or uniform rectangular array. In some exemplary embodiments, the array may be a non-uniform array.

In some exemplary embodiments, the plurality of resonant tunneling diode elements comprises more than 64 resonant tunneling diode elements, for example more than 1000 resonant tunneling diode elements. In some exemplary embodiments, a comparatively large number of resonant tunneling diode elements may be reliably synchronized using the optical synchronization signal according to exemplary embodiments.

In some exemplary embodiments, the predetermined resonance frequency of the plurality of resonant tunneling diode elements is between 1 GHz and 100 THz.

In some exemplary embodiments, the predetermined resonance frequency of the plurality of resonant tunneling diode elements is between 24 GHz and 70 GHz or above.

In some exemplary embodiments, the predetermined resonance frequency of the plurality of resonant tunneling diode elements is e.g. between 110 GHz and 170 GHz, e.g. covering the D-band.

In some exemplary embodiments, the predetermined resonance frequency of the plurality of resonant tunneling diode elements is between 1 THz and 100 THz.

In some exemplary embodiments, at least one resonant tunneling diode element of the plurality of resonant tunneling diode elements comprises a controllable phase shifter configured to modify a phase of the optical synchronization signal.

In some exemplary embodiments, the controllable phase shifter comprises a material a permittivity of which can be controlled, e.g. by applying a control signal, e.g. control voltage, to the material. In some exemplary embodiments, this e.g. enables to modify the phase of the optical synchronization signal.

In some exemplary embodiments, the material may e.g. be or comprise an electrochromic (EC-) material.

In some exemplary embodiments, the material may comprise other material with controllable permittivity, such as e.g. liquid crystal material.

In some exemplary embodiments, more than one resonant tunneling diode element of the plurality of resonant tunneling diode elements, e.g. all of the plurality of resonant tunneling diode elements, comprise a respective, e.g. individual, phase shifter, wherein a phase of the optical synchronization signal may e.g. be individually controlled for respective resonant tunneling diode elements.

In some exemplary embodiments, the plurality of resonant tunneling diode elements comprises two or more groups of resonant tunneling diode elements, wherein one phase shifter is e.g. assigned to one of the groups of resonant tunneling diode elements. This e.g. enables to modify a phase shift of the optical synchronization signal on a per group basis for the respective resonant tunneling diode elements.

In some exemplary embodiments, the apparatus is configured to modify the phase of the optical synchronization signal by means of the controllable phase shifter to perform at least one of: a) compensating a phase shift of the optical synchronization signal for the at least one resonant tunneling diode element, e.g. with respect to other resonant tunneling diode elements of the plurality of resonant tunneling diode elements (thus e.g. dynamically (during an operation of the apparatus) compensating phase differences which may e.g. be caused by temperature and/or other drift effects or which are caused by manufacturing and/or design (e.g. different lengths of optical feeds)), b) calibration, e.g. of individual signal transmission paths, e.g. for providing the optical synchronization signal to the at least one resonant tunneling diode element, c) beamforming, e.g. when providing output signals of the plurality of resonant tunneling diode elements to an antenna system comprising one or more antenna elements, d) providing a predetermined delay and/or phase to an output signal of the at least one resonant tunneling diode. In some exemplary embodiments, any combination of the aforementioned aspects a), b), c), d) may be used.

In some exemplary embodiments, at least one resonant tunneling diode element of the plurality of resonant tunneling diode elements is arranged on a carrier element, e.g. a substrate, e.g. comprising a semiconductor material and/or another suitable substrate material such as ceramics or the like.

In some exemplary embodiments, an illumination device is provided which is configured to provide the optical synchronization signal to at least one resonant tunneling diode element of the plurality of resonant tunneling diode elements.

In some exemplary embodiments, the illumination device is configured to provide the optical synchronization signal to Several ones, for example all, of the plurality of resonant tunneling diode elements.

In some exemplary embodiments, the illumination device comprises at least one optical element, wherein for example the at least one optical element comprises at least one of: a) an optical fiber, b) a lens, c) a light guide, d) a light spreading element.

In some exemplary embodiments, the controllable phase shifter is arranged between at least one component of the illumination device and the at least one resonant tunneling diode element.

Further exemplary embodiments relate to a method of manufacturing an apparatus comprising a plurality of resonant tunneling diode, RTD, elements, comprising: providing the plurality of resonant tunneling diode, RTD, elements, for example on a common carrier, providing a synchronization signal source configured to provide an optical synchronization signal to the plurality of resonant tunneling diode elements.

In some exemplary embodiments, the method comprises at least one of: a) providing a controllable phase shifter configured to modify a phase of the optical synchronization signal for at least one resonant tunneling diode element of the plurality of resonant tunneling diode elements, b) providing at least one illumination device configured to provide the optical synchronization signal to at least one resonant tunneling diode element of the plurality of resonant tunneling diode elements.

Further exemplary embodiments relate to an apparatus comprising a plurality of resonant tunneling diode elements and synchronization means configured to provide an optical synchronization signal to the plurality of resonant tunneling diode elements.

Further exemplary embodiments relate to an antenna system comprising one or more antenna elements and at least one apparatus according to the embodiments.

In some exemplary embodiments, the apparatus according to the embodiments may e.g. be used as a signal source for radio frequency signals, e.g. in at least one of the exemplarily mentioned frequency range, e.g. between 1 GHz and 100 THz.

In some exemplary embodiments, the apparatus according to the embodiments may e.g. be used within a transmit (tx) path of a radio device such as e.g. a radio transmitter.

In some exemplary embodiments, the apparatus according to the embodiments may e.g. be used within a receive (rx) path of a radio device such as e.g. a radio receiver.

In some exemplary embodiments, the apparatus according to the embodiments may e.g. be used within a transceiver.

In some exemplary embodiments, the apparatus according to the embodiments may e.g. be used to synchronize a plurality, e.g. multitude, of, e.g. spatially distributed, transmitters and/or receivers and/or transceivers.

In some exemplary embodiments, the apparatus according to the embodiments may e.g. be used to provide a local oscillator signal, e.g. for use within at least one of: a) a receiver, b) a transmitter, c) a transceiver.

Further exemplary embodiments relate to a method of operating an apparatus comprising a plurality of resonant tunneling diode, RTD, elements and a synchronization signal source configured to provide an optical synchronization signal to the plurality of resonant tunneling diode elements, the method comprising: generating, by means of the plurality of resonant tunneling diode, RTD, elements, radio frequency signals, synchronizing the plurality of resonant tunneling diode, RTD, elements with each other based on the optical synchronization signal.

In some exemplary embodiments, the method comprises at least one of: a) applying a phase shift to the optical synchronization signal by means of a controllable phase shifter, b) using at least one illumination device for providing the optical synchronization signal to at least one resonant tunneling diode element of the plurality of resonant tunneling diode elements, c) applying a control signal, for example control voltage, to at least one of cl) a controllable phase shifter, c2) a resonant tunneling diode element, c3) a frequency determining component associated with the resonant tunneling diode element.

Further exemplary embodiments relate to a use of the apparatus according to the embodiments and/or of the method according to the embodiments for at least one of: a) synchronizing the plurality of resonant tunneling diode elements with each other, e.g. by injection locking using the optical synchronization signal, b) providing multiple synchronized radio frequency, RF, signals, c) combining, e.g. coherently combining, multiple synchronized radio frequency, RF, signals, d) providing radio frequency signals in the THz and/or sub-THz range, e.g. having a power level lower than 0.1 mw, or, for example, higher than 0.1 mW, e.g. for sub-THz systems, e) providing an optically synchronized resonant tunneling diode-based array, e.g. for a radio device such as e.g. a transmitter and/or receiver and/or transceiver, e.g. comprising a multi-antenna system.

### BRIEF DESCRIPTION OF THE FIGURES

FIG. 1 schematically depicts a simplified block diagram according to some exemplary embodiments,

FIG. 2A schematically depicts a simplified top view according to some exemplary embodiments,

FIG. 2B schematically depicts a simplified top view according to some exemplary embodiments,

FIG. 3A schematically depicts a simplified diagram according to some exemplary embodiments,

FIG. 3B schematically depicts a simplified circuit diagram according to some exemplary embodiments,

FIG. 4 schematically depicts a simplified block diagram according to some exemplary embodiments,

FIG. 5 schematically depicts a simplified perspective view according to some exemplary embodiments,

FIG. 6 schematically depicts a simplified perspective view according to some exemplary embodiments,

FIG. 7 schematically depicts a simplified perspective view according to some exemplary embodiments,

FIG. 8 schematically depicts a simplified diagram according to some exemplary embodiments,

FIG. 9A schematically depicts a simplified top view according to some exemplary embodiments,

FIG. 9B schematically depicts a simplified side view according to some exemplary embodiments,

FIG. 10 schematically depicts a simplified block diagram according to some exemplary embodiments,

FIG. 11 schematically depicts a simplified block diagram according to some exemplary embodiments,

FIG. 12 schematically depicts a simplified block diagram according to some exemplary embodiments,

FIG. 13A schematically depicts a simplified flow-chart according to some exemplary embodiments,

FIG. 13B schematically depicts a simplified flow-chart according to some exemplary embodiments,

FIG. 14 schematically depicts a simplified block diagram according to some exemplary embodiments,

FIG. 15 schematically depicts a simplified block diagram according to some exemplary embodiments,

FIG. 16A schematically depicts a simplified flow-chart according to some exemplary embodiments,

FIG. 16B schematically depicts a simplified flow-chart according to some exemplary embodiments,

FIG. 17 schematically depicts a simplified flow-chart according to some exemplary embodiments, and

FIG. 18 schematically depicts aspects of use according to some exemplary embodiments.

### DESCRIPTION OF SOME EXEMPLARY EMBODIMENTS

Some exemplary embodiments, see for example FIG. 1, relate to an apparatus 100 comprising a plurality of resonant tunneling diode, RTD, elements 110-1, 110-2, . . . and a synchronization signal source 120 configured to provide an optical synchronization signal SYNC-SIG to the plurality of resonant tunneling diode elements 110-1, 110-2, . . . . In some exemplary embodiments, this enables to synchronize several ones, for example all, of the plurality of resonant tunneling diode elements 110-1, 110-2, . . . , whereby, for example, optically synchronized radio frequency oscillators based on the respective resonant tunneling diode elements 110-1, 110-2, . . . may be provided, which output corresponding radio frequency output signals os-110-1, os-110-2, . . . . In some exemplary embodiments, the output signals os-110-1, os-110-2, . . . may e.g. be provided to an antenna system 10 comprising one or more antenna elements, and/or to other devices processing radio frequency signals.

In other words, in some exemplary embodiments, the plurality of resonant tunneling diode elements 110-1, 110-2, . . . are light sensitive, e.g. sensitive at least to the optical synchronization signal SYNC-SIG, and may thus be optically synchronized using the optical synchronization signal SYNC-SIG.

In some exemplary embodiments, the proposed optical synchronization enables to provide precisely synchronized resonant tunneling diode elements 110-1, 110-2, . . . , thus e.g. enabling to coherently combine respective output signals os-110-1, os-110-2, . . . of the synchronized resonant tunneling diode elements 110-1, 110-2, . . . , wherein, in some exemplary embodiments, e.g. higher signal powers can be attained.

In some exemplary embodiments, each of the plurality of resonant tunneling diode elements 110-1, 110-2, . . . is configured to oscillate at a predetermined resonance frequency, wherein, for example, the optical synchronization signal SYNC-SIG comprises the predetermined resonance frequency.

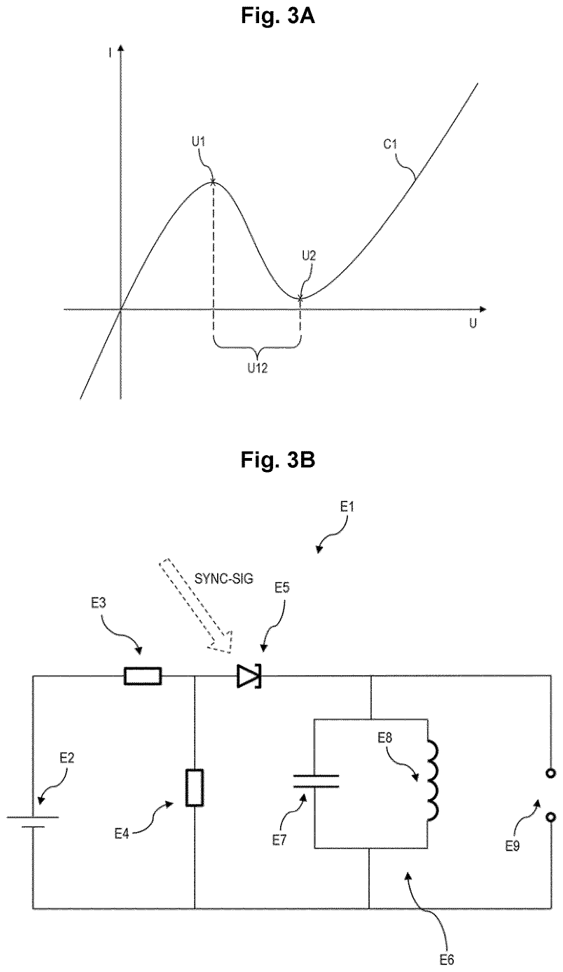

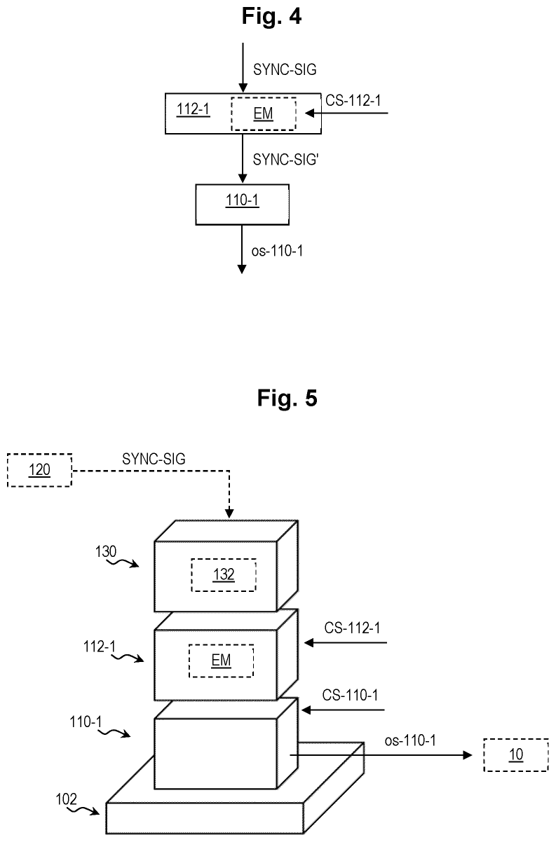

In some exemplary embodiments, at least some resonant tunneling diode elements of the plurality of resonant tunneling diode elements 110-1, 110-2, . . . , e.g. all of the plurality of resonant tunneling diode elements 110-1, 110-2, . . . , may comprise one or more (e.g., further) electronic components (see, for example, FIG. 3B, which is explained further below), e.g. to provide a resonator circuit based on the respective resonant tunneling diode element.

In some exemplary embodiments, FIG. 1, the apparatus 100 is configured to effect a phase synchronization of the plurality of resonant tunneling diode elements 110-1, 110-2, . . . by means of injection locking of the plurality of resonant tunneling diode elements using the optical synchronization signal SYNC-SIG.

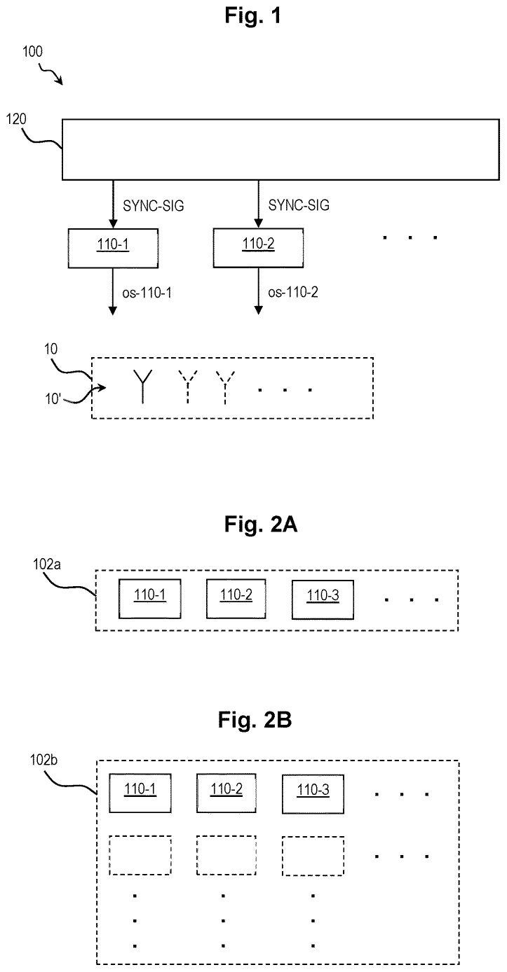

In some exemplary embodiments, FIGS. 2A, 2B, the plurality of resonant tunneling diode elements are arranged in form of an array, wherein the array is at least one of: a) a one-dimensional array (FIG. 2A), b) a two-dimensional array (FIG. 2B), c) a three-dimensional array (not shown). In some exemplary embodiments, the array may e.g. be a uniform array, e.g. uniform linear array or uniform rectangular array.

In some exemplary embodiments, the array may be a non-uniform array. In some exemplary embodiments, the non-uniform array comprises non-regular, e.g. non-periodic, e.g. pseudo-random or random, spatial distribution of resonant tunneling diode elements.

In some exemplary embodiments, FIGS. 2A, 2B, the array may comprise a carrier 102a, 102b, such as e.g. a common substrate, wherein at least some, for example all, resonant tunneling diode elements of the array are arranged on.

In some exemplary embodiments, the plurality of resonant tunneling diode elements comprises more than 64 resonant tunneling diode elements, for example more than 1000 resonant tunneling diode elements. In some exemplary embodiments, a comparatively large number of resonant tunneling diode elements may be reliably synchronized using the optical synchronization signal SYNC-SIG (FIG. 1) according to exemplary embodiments.

In some exemplary embodiments, the predetermined resonance frequency of the plurality of resonant tunneling diode elements is between 1 GHz and 100 THz.

In some exemplary embodiments, the predetermined resonance frequency of the plurality of resonant tunneling diode elements is between 24 GHz and 70 GHz or above.

In some exemplary embodiments, the predetermined resonance frequency of the plurality of resonant tunneling diode elements is e.g. between 110 GHz and 170 GHz, e.g. covering the D-band.

In some exemplary embodiments, the predetermined resonance frequency of the plurality of resonant tunneling diode elements is between 1 THz and 100 THz.

FIG. 3A schematically depicts a simplified diagram according to some exemplary embodiments depicting an exemplary current-voltage characteristic of a resonant tunneling diode element according to some embodiments. A current I through the resonant tunneling diode element is depicted on a vertical axis, and a voltage U at the resonant tunneling diode element is depicted on a horizontal axis of FIG. 3A.

From FIG. 3A, it can be seen that with increasing voltage U, the current I will increase, up to a first point U1. After that, the current I will decrease with increasing voltage U, up to a second point U2. After that, e.g. with increasing voltage from second point U2, the current I will increase again. This means that the resonant tunneling diode element comprises a negative differential resistance in the voltage region U12, as the current I is decreasing with increasing voltage U.

Thus, in some exemplary embodiments, one or more resonant tunneling diode elements 110-1, 110-2, . . . (FIG. 1) may be operated at least temporarily within the voltage region U12 as exemplarily depicted by FIG. 3A thus exploiting the operational behavior associated with the negative differential resistance, which e.g. enables to provide oscillator circuits operating in a GHz or THz frequency range.

FIG. 3B schematically depicts a simplified circuit diagram according to some exemplary embodiments, representing an oscillator circuit based on a resonant tunneling diode element. The oscillator circuit E1 comprises a voltage source E2 for applying an operating voltage and a voltage divider comprising a first resistor E3 and a second resistor E4. Element E5 symbolizes a resonant tunneling diode element. The oscillator circuit E1 further comprises an LC-type oscillator E6 comprising a capacitive element E7 and an inductive element E8 connected parallel to each other. In some exemplary embodiments, the oscillator circuit E1 is configured to provide at its output E9 an oscillating output voltage (see also output signal os-110-1 of FIG. 1, for example), e.g. in a GHz or THz frequency range, e.g., inter alia, depending on the values of the components E7, E8.

In some exemplary embodiments, at least one resonant tunneling diode element 110-1, 110-2, . . . (FIG. 1) of the plurality of resonant tunneling diode elements comprises an oscillator circuit E1 as exemplarily depicted by FIG. 3B. In some exemplary embodiments, other oscillator topologies are also conceivable.

FIG. 3B additionally depicts the optical synchronization signal which enables to optically synchronize the resonant tunneling diode element E5 and thus the oscillator circuit E1, e.g. with further resonant tunneling diode element(s) (not shown in FIG. 3B).

In some exemplary embodiments, FIG. 4, at least one resonant tunneling diode element 110-1 of the plurality of resonant tunneling diode elements comprises a controllable phase shifter 112-1 configured to modify a phase of the optical synchronization signal SYNC-SIG, whereby e.g. a modified optical synchronization signal SYNC-SIG′ may be obtained.

In some exemplary embodiments, FIG. 4, the controllable phase shifter 112-1 comprises a material EM a permittivity of which can be controlled, e.g. by applying a control signal, e.g. control voltage, to the material. In some exemplary embodiments, this e.g. enables to modify the phase of the optical synchronization signal SYNC-SIG, e.g. based on the control voltage CS-112-1, and thus, for example, also the phase of the output signal os-110-1 of the resonant tunneling diode element 110-1.

In some exemplary embodiments, the material EM may e.g. be or comprise an electrochromic (EC-) material.

In some exemplary embodiments, the material EM may comprise other material with controllable permittivity, such as e.g. liquid crystal material.

In some exemplary embodiments, the permittivity of the material EM is controllable within a spectral range of the optical synchronization signal SYNC-SIG, which may e.g. be beneficial if the permittivity is frequency-dependent.

In some exemplary embodiments, FIG. 1, more than one resonant tunneling diode element 110-1, 110-2, . . . of the plurality of resonant tunneling diode elements, e.g. all of the plurality of resonant tunneling diode elements, comprise a respective, e.g. individual, phase shifter 112-1 (FIG. 4), wherein a phase of the optical synchronization signal SYNC-SIG may e.g. be individually controlled for respective resonant tunneling diode elements.

In some exemplary embodiments, the plurality of resonant tunneling diode elements comprises two or more groups of resonant tunneling diode elements, wherein one phase shifter 112-1 is e.g. assigned to one of the groups of resonant tunneling diode elements. This e.g. enables to modify a phase shift of the optical synchronization signal on a per group basis for the respective resonant tunneling diode elements.

In some exemplary embodiments, FIG. 1, the apparatus 100 is configured to modify the phase of the optical synchronization signal SYNC-SIG by means of the, e.g. individually, controllable phase shifter 112-1 (FIG. 4) to perform at least one of: a) compensating a phase shift of the optical synchronization signal SYNC-SIG for the at least one resonant tunneling diode element, e.g. with respect to other resonant tunneling diode elements of the plurality of resonant tunneling diode elements (thus e.g. dynamically (during an operation of the apparatus 100) compensating phase differences which may e.g. be caused by temperature and/or other drift effects), b) calibration, e.g. of individual signal transmission paths, e.g. for providing the optical synchronization signal to the at least one resonant tunneling diode element (e.g., before and/or during operation), c) beamforming, e.g. when providing output signals os-110-1, os-110-2, . . . (FIG. 1) of the plurality of resonant tunneling diode elements to an antenna system 10 comprising one or more antenna elements 10′, d) providing a predetermined delay and/or phase to an output signal os-110-1 of the at least one resonant tunneling diode element 110-1.

In some exemplary embodiments, even differences, e.g. fix or static differences, as may e.g. be caused by design (e.g., difference in fiber lengths) and/or manufacturing tolerances, etc. may be compensated, e.g. by modifying the phase of the optical synchronization signal SYNC-SIG, e.g. by means of the controllable phase shifter 112-1. In some exemplary embodiments, such compensating may e.g. even be done before an operation (also, e.g. by look-up-tables), and, in some exemplary embodiments, adaptive effects and e.g. a related compensation of the adaptive effects during operation may come on top, e.g. may be performed, e.g. additionally to a fiber length compensation or the like.

In some exemplary embodiments, FIG. 5, at least one resonant tunneling diode element 110-1 of the plurality of resonant tunneling diode elements is arranged on a carrier element 102, e.g. a substrate, e.g. comprising a semiconductor material and/or another suitable substrate material such as ceramics or the like.

In some exemplary embodiments, FIG. 5, an illumination device 130 is provided which is configured to provide the optical synchronization signal SYNC-SIG (as e.g. received by the illumination device 130 from the synchronization signal source 120) to at least one resonant tunneling diode element 110-1 of the plurality of resonant tunneling diode elements.

In some exemplary embodiments, FIG. 5, a control signal CS-110-1, e.g. a control voltage, e.g. bias voltage, may be applied to the at least one resonant tunneling diode element 110-1, e.g. to control an operation thereof, e.g. to modify a frequency of an oscillator circuit based thereon (see, for example, FIG. 3B) and/or to modify an amplitude of the output signal os-110-1, which may e.g. be provided to an optional antenna system 10.

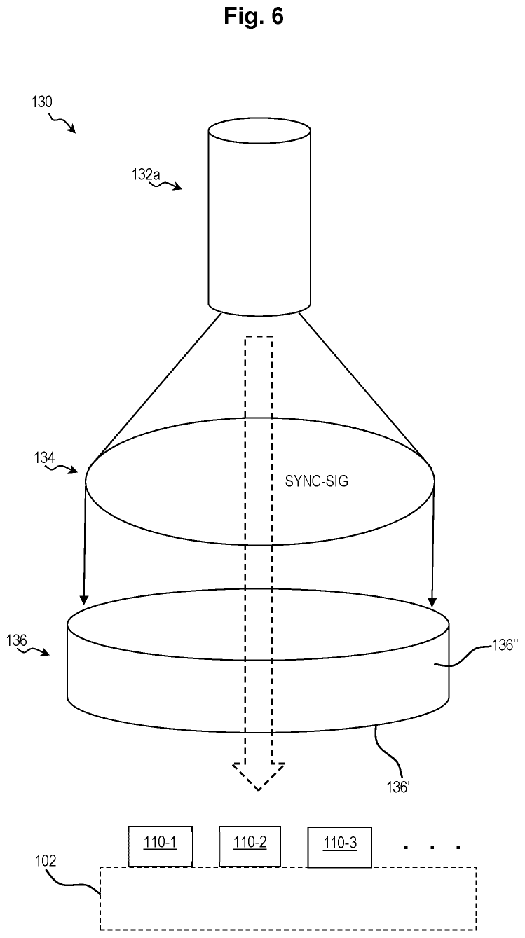

In some exemplary embodiments, FIG. 5, the illumination device 130 is configured to provide the optical synchronization signal SYNC-SIG to several ones, for example all, of the plurality of resonant tunneling diode elements (not shown in FIG. 5, see, for example, FIG. 6).

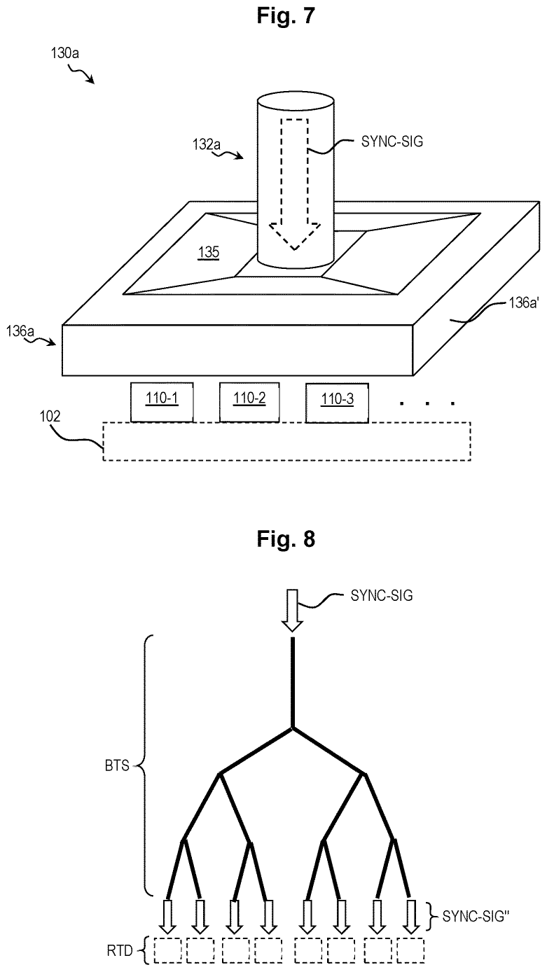

In some exemplary embodiments, FIGS. 5, 6, the illumination device 130 comprises at least one optical element 132, wherein for example the at least one optical element 132 comprises at least one of: a) an optical fiber 132a (e.g., for guiding the optical synchronization signal SYNC-SIG from the synchronization signal source 120 (FIG. 1)), b) a lens 134 (e.g., for shaping an electromagnetic field associated with the optical synchronization signal SYNC-SIG, e.g. at an output of the optical fiber 132a), c) a light guide or optical waveguide 136, d) a light spreading element 135 (FIG. 7).

As can be seen from FIG. 6, in some exemplary embodiments, the optical synchronization signal SYNC-SIG is distributed by lens 134 to the light guide 136 which transmits the optical synchronization signal SYNC-SIG to a plurality of resonant tunneling diode elements 110-1, 110-2, 110-3, . . . arranged adjacent to an output surface 136′ thereof facing the carrier 102 the resonant tunneling diode elements 110-1, 110-2, 110-3, . . . are arranged on.

In some exemplary embodiments, an outer side surface 136″ of the light guide 136 may be non-transparent, e.g. absorbing, e.g. for the optical synchronization signal SYNC-SIG. In some exemplary embodiments, a non-transparent, e.g. absorbing, coating (not shown) may be provided on the outer side surface 136″ of the light guide 136.

FIG. 7 schematically depicts a configuration of an illuminating device 130a similar to FIG. 6, wherein, however, a light spreading element 135 is provided to, e.g. evenly, distribute, e.g. spread, the optical synchronization signal SYNC-SIG as received from the optical fiber 132 to a light guide 136a.

In some exemplary embodiments, FIGS. 6, 7, the light guides 136, 136a may comprise different sections comprising different optical properties, e.g. to apply different propagation delay(s) and/or different phase shifts to portions of the optical synchronization signal SYNC-SIG traveling through the light guides 136, 136a, e.g. to provide different ones of the resonant tunneling diode elements 110-1, 110-2, 110-3, . . . with a respectively differently delayed and/or phase shifted portion of the optical synchronization signal SYNC-SIG.

In some exemplary embodiments, and as already mentioned above, the configurations of FIGS. 6, 7 may e.g. be used to provide an optical signal provisioning structure for providing the optical synchronization signal SYNC-SIG to one or more RTD elements.

In some exemplary embodiments, the optical fiber 132a may e.g. be provided at a central position of the optical signal provisioning structure and/or of the RTD element-based array, respectively. In other words, in some exemplary embodiments, through this fiber 132a, the optical synchronization signal SYNC-SIG may be fed in a central manner.

In some exemplary embodiments, e.g. in order to subsequently feed the optical synchronization signal SYNC-SIG, e.g. to spatially distributed RTD elements, two possibilities are proposed: First, an optical lens 134 (see FIG. 6, probably better suited for circular array shapes, at least in some exemplary embodiments) can be used which e.g. ensures a phase alignment of the optical synchronization signal SYNC-SIG portions, e.g. at a plane surface perpendicular to the lens 134, see FIG. 6. Second, a light spreading element, e.g. layer, 135 follows the fiber 132a, some exemplary aspects of which are discussed in more detail in the following paragraph, See also FIG. 7.

In some exemplary embodiments, the light spreading layer 135 may cover the full RTD element array and may e.g. ensure that a central optically provided optical synchronization signal is evenly, e.g. equally, distributed and fed to the individual RTD elements of the RTD element array.

In some exemplary embodiments, FIG. 7, the light guide 136a, which may e.g. be configured to ensure sufficient illumination with the optical synchronization signal for each RTD element of the RTD element array is provided. In some exemplary embodiments, the light guide 136a may e.g. be framed by light absorbing side walls 136a′ in order to e.g. prevent reflections and thus possible synchronization issues which may e.g. be caused by reflected light and their related additional phases.

In some exemplary embodiments, FIGS. 6, 7, the light guide 136, 136a may e.g. comprise optical splitters as well as light guide elements, in some exemplary embodiments e.g. configured and/or arranged in a way that it ensures almost same lengths and thus phase-aligned light guide paths (also see the structure BTS of FIG. 8 explained further below), by this e.g. reducing or even omitting an effort for later phase alignment.

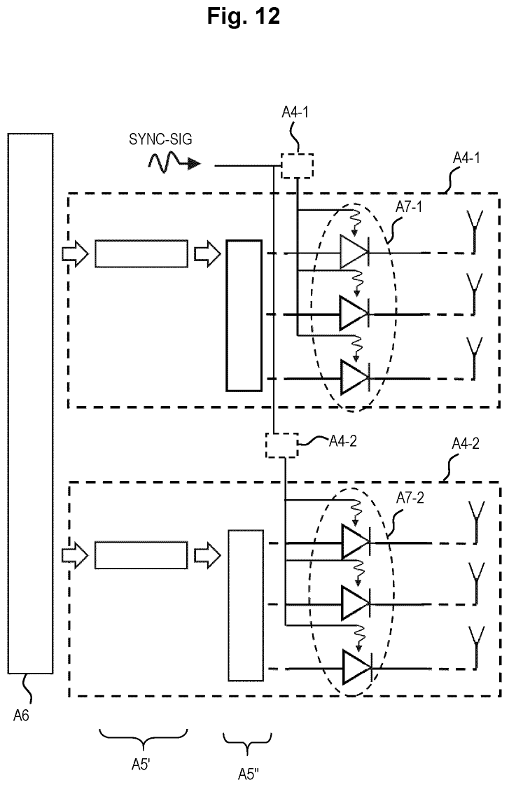

In some exemplary embodiments, the light guide 136, 136a of FIGS. 6, 7 may e.g. be combined with a hybrid sub-array architecture (see FIG. 12 explained further below).

In some exemplary embodiments, the light guide 136, 136a may e.g. comprise combination(s) of transparent material layers (e.g., transparent for the optical synchronization signal SYNC-SIG), e.g. with different delays and thicknesses (e.g., per feed path or feed path group).

In some exemplary embodiments, building sub-groups of small overall dimension/area, e.g. of close-by RTD elements, e.g. to be commonly illuminated with the optical synchronization signal SYNC-SIG, may also be an approach, e.g. to limit illumination/distribution network complexity.

FIG. 8 schematically illustrates a distribution of the optical synchronization signal SYNC-SIG as e.g. effected by an exemplary illuminating device 130, 130a and/or a component 136, 136a thereof according to further exemplary embodiments. A binary tree-type structure BTS schematically illustrates a distribution of the optical synchronization signal SYNC-SIG to a plurality of different resonant tunneling diode elements 110-1, 110-2, 110-3, . . . collectively denoted as “RTD” in FIG. 8 according to some exemplary embodiments, wherein respective individual portions SYNC-SIG″ of the optical synchronization signal SYNC-SIG are output to the individual resonant tunneling diode elements 110-1, 110-2, 110-3, . . . .

In some exemplary embodiments, FIG. 5, the controllable phase shifter 112-1 is arranged between at least one component 132 of the illumination device 130 and the at least one resonant tunneling diode element 110-1.

Returning to FIG. 5, in some exemplary embodiments, the configuration depicted by FIG. 5 represents an exemplary structure of a single, basic, scalable resonant tunneling diode element segment enabling to employ the principle according to the embodiments. In some exemplary embodiments, a plurality of the structure as depicted by FIG. 5 may be provided for enabling optical synchronization of several resonant tunneling diode elements.

In some exemplary embodiments, a main function of the material EM, e.g. electro-chromic material EM, is e.g. firstly to compensate a phase, e.g. appearing due to a spatial distribution with respect to a, for example central, optical synchronization signal provision point (e.g., the synchronization signal source 120, see FIG. 1). Note, however, that, e.g. in case of an optical lens 134 used for distributing the synchronization signal according to some exemplary embodiments, no significant phase differences may be expected, e.g. besides a spherical aberration effect.

In some exemplary embodiments, the e.g. EC-material EM may represent a bias/voltage controllable phase shifter, e.g. to compensate the abovementioned phase differences which in some exemplary embodiments may appear, e.g. in an RTD-element based antenna array comprising a large number of basic elements as e.g. shown by FIG. 5.

As an example, e.g. assuming an array size of 1 cm\hat{ }2 and a light guide-based distribution network for the optical synchronization signal, a light signal may need ~30 . . . 50 ps (e.g., depending on the dielectric material of the light guide) to propagate from one end to the other end of the array. In some exemplary embodiments, this may e.g. be put in relation to a duration of e.g. one oscillation period of e.g. a mmWave-carrier signal, which may e.g. be generated by the at least one RTD element, which may e.g. be ~7 ps, e.g. for an 140 GHz carrier signal (e.g., D-band).

In some exemplary embodiments, the EC-material EM of the phase shifter 112-1 can, e.g. also, be used for applying calibration weights (e.g. characterizing and/or compensating delay and/or phase differences, e.g. between at least some of the resonant tunnelling diode elements), e.g. determined for the RTD-based array.

In some exemplary embodiments, the EC-material EM of the phase shifter 112-1 can, e.g. also, be used for applying individual antenna beamforming phase weights, as e.g. determined by a beamformer, e.g. steered to a user position based on some channel state information (CSI) such as angle of departure.

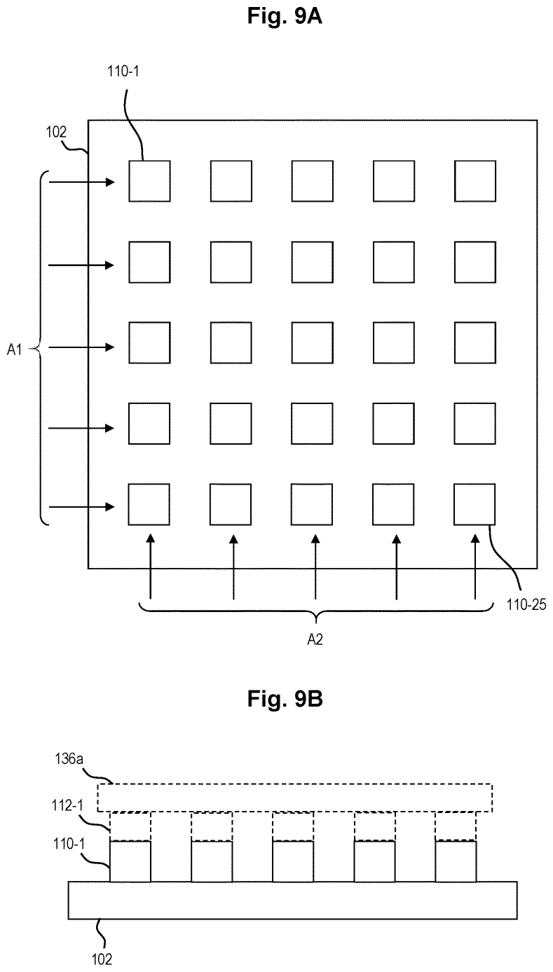

FIG. 9A schematically depicts a top view according to further exemplary embodiments. Depicted is a rectangular array of, presently for example twenty-five, resonant tunneling diode elements only two of which are denoted with reference signs 110-1 and 110-25, for the sake of intelligibility. Each of the twenty-five resonant tunneling diode elements of FIG. 9A may e.g. comprise the structure as exemplarily depicted by FIG. 5, e.g. comprising an individual phase shifter 112-1, also see the schematic side view of FIG. 9B.

In some exemplary embodiments, however, a common illuminating device as e.g. exemplarily depicted by FIG. 7 may be provided for the array of FIGS. 9A, 9B, wherein the light guide 136a is depicted by FIG. 9B.

Arrows A1 of FIG. 9A exemplarily depict first control signals, e.g. control voltages, which may e.g. be applied to respective (e.g., EC-material-based) phase shifters 112-1, . . . of the array of FIGS. 9A, 9B. Note that while only five arrows A1 are exemplarily depicted by FIG. 9A, twenty-five (or, in some embodiments, more than five, but e.g. less than twenty-five) control signals, e.g. control voltages, may be provided to the respective phase shifters of FIG. 9A, which e.g. enables to individually control a respective phase shift of a portion of the optical synchronization signal as applied to the individual resonant tunneling diode elements 110-1, . . . , 110-25.

Arrows A2 of FIG. 9A exemplarily depict second control signals, e.g. control voltages, which may e.g. be applied to respective resonant tunneling diode elements 110-1, . . . , 110-25. Note that while only five arrows A2 are exemplarily depicted by FIG. 9A, twenty-five (or, in some embodiments, more than five, but e.g. less than twenty-five) control signals, e.g. control voltages, may be provided to the respective resonant tunneling diode elements 110-1, . . . , 110-25 of FIG. 9A, which e.g. enables to individually control a respective amplitude and/or frequency and/or other aspects of operation of the individual resonant tunneling diode elements 110-1, . . . , 110-25.

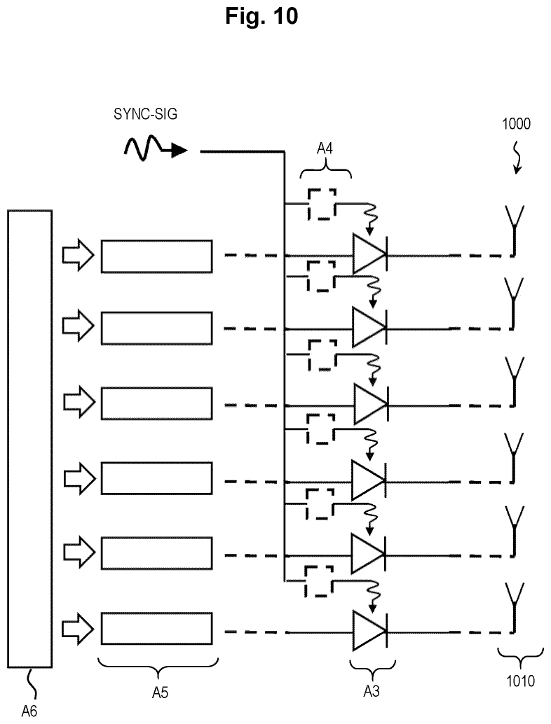

FIG. 10 schematically depicts a simplified block diagram according to some exemplary embodiments. Depicted is a, for example fully digital, multi-antenna architecture comprising an antenna system 1000 that has a plurality of antenna elements 1010.

In some exemplary embodiments, an accurate synchronization of the antenna paths of multi-antenna arrays such as of the antenna system 1000 can be important, e.g. a crucial requirement, e.g. in order to enable e.g. beamforming and to achieve good/high system performance.

In some exemplary embodiments, e.g. especially for higher frequency ranges (mm-wave, sub-THz, THz), using some conventional approaches, the accurate synchronization of multiple antenna paths becomes more and more challenging, e.g. due to the fact that the wavelengths become very short, thus requiring e.g. synchronization alignment in the picosecond (ps) or even femtosecond (fs) range.

Further, in some exemplary embodiments, e.g. for large multi-antenna systems which e.g. comprise a large number of antennas (e.g. in the order of thousands) and thus may e.g. comprise comparable large overall dimensions/areas, a synchronization may be beneficial.

In other words, for multi-antenna arrays especially in high frequency ranges, the principle according to the embodiments may beneficially applied, e.g. using an optical (e.g., optically distributed) synchronization signal SNYC-SIG (FIG. 10), e.g. combined with injection locking of resonant tunneling diode elements, whereby, in some exemplary embodiments, an accurate synchronization of e.g. all resonant tunneling diode elements and/or 1010 antennas of a resonant tunneling diode element-based multi-antenna array can be attained.

In this regard, FIG. 10 exemplarily depicts a fully digital multi-antenna system architecture according to exemplary embodiments. Element A3 symbolizes resonant tunneling diode elements associated with a respective antenna path each, and element A4 symbolizes optional individual phase shifters associated with each resonant tunneling diode element A3, e.g. to modify a phase of the optical synchronization signal SYNC-SIG.

As exemplary illustrated by FIG. 10, in some exemplary embodiments, a, for example central, optical sync signal SYNC-SIG is distributed (e.g., by a fiber network or an optical lens) and provided to each resonant tunneling diode element A3.

In some exemplary embodiments, e.g. in order to compensate for phase differences appearing due to potentially comparatively large physical dimensions of the multi-antenna system 1000, e.g. with respect to a small wavelength, but e.g. also due to component tolerances, the controllable, e.g. adjustable, phase shifters A4 are provided, e.g. for each path/for each resonant tunneling diode element A3, thus e.g. allowing to compensate for phase differences flexibly and to enable accurate overall multi-antenna synchronization.

In some exemplary embodiments, since an optical synchronisation network for providing, e.g. distributing, the optical synchronisation signal SYNC-SIG, is more or less a passive network, individual settings for phase alignment within the optical distribution network may e.g. be assumed to be stable, e.g. once being determined and applied, thus, in some exemplary embodiments, most probably not requiring further, e.g. regular, adjustment.

In some exemplary embodiments, an optical synchronisation network for providing, e.g. distributing, the optical synchronisation signal SYNC-SIG may also comprise one or more amplifier units, e.g. for amplifying the optical synchronisation signal SYNC-SIG.

Elements A5 of FIG. 10 symbolize optional signal provision blocks providing individual signals for the plurality of antenna paths of the antenna system 1010 in a per se known manner, e.g. based on signals from a, for example digital, front end A5.

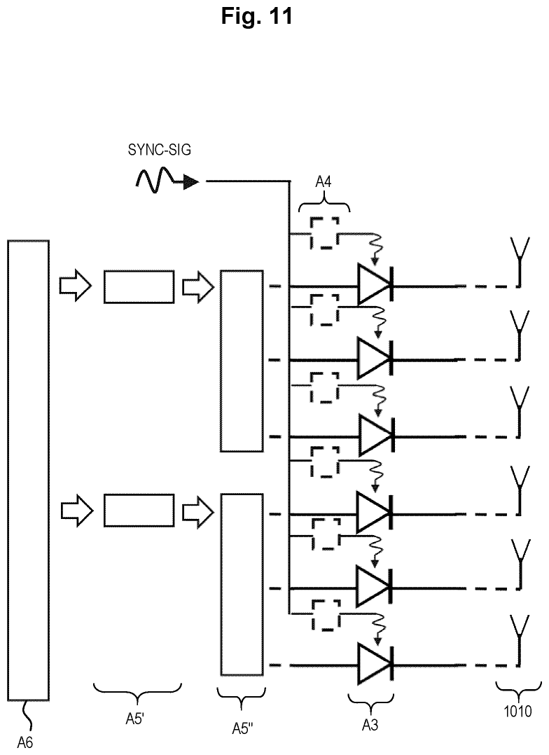

FIG. 11 depicts a configuration for a multi-antenna system according to further exemplary embodiments, which is similar to FIG. 10, but which comprises two signal provision blocks A5′ providing respective signals to two splitters A5″, which are configured to split their respective input signals for output to respective antenna paths, as exemplarily depicted by FIG. 11. In some exemplary embodiments, the configuration of FIG. 11 may be denoted as a hybrid multi-antenna architecture. In some exemplary embodiments, and similar to the FIG. 10 configuration, the exemplary configuration of FIG. 11 also provides for an optical synchronization signal SYNC-SIG applied via phase shifters A4 to resonant tunneling diode elements A3.

In some exemplary embodiments, FIG. 12, e.g. if the optical synchronization network can be designed and realized accurately enough (e.g. within smaller sub-arrays or by adequate optical feeding network design as shown by FIG. 8) a reduced number of phase shifters may be provided, e.g. (as indicated by FIG. 2) one phase shifter A4-1, A4-2 per group of, e.g. three, antenna paths. As an example, the dashed ellipses A7-1, A7-2 of FIG. 12 symbolize respective groups of components which are, according to some exemplary embodiments, sufficiently precisely coupled with each other/supplied with the optical synchronization signal SYNC-SIG, so that individual “intra-group” phase shifters within the groups A7-1, A7-2 are not required in some exemplary embodiments.

In some exemplary embodiments (not shown in FIG. 12), no phase shifter(s) are provided.

While some exemplary embodiments explained above with reference to FIG. 10 to FIG. 12 focus on a transmit direction, the principle according to the embodiments is also applicable to a receive direction (not shown).

In some exemplary embodiments, e.g. since an optical distribution network for providing the synchronization signal SYNC-SIG is a passive network comprising of optical components such as e.g. optical fibers and/or optical guide structures, and/or an optical lens, the optical distribution network can be assumed to be relatively stable with respect to phase over time. E.g., in some exemplary embodiments, due to small dimensions (e.g. max. a few cm\hat{ }2) of a sub-THz or THz multi-antenna array, e.g. an ambient temperature/situation (as e.g. caused by sun, shadow, etc.) may be assumed as having a same impact for the whole, comparatively small, e.g. tiny, array.

Thus, in some exemplary embodiments, an initial phase may be provided related to a calibration procedure, e.g. for individual resonant tunneling diode element and/or antenna paths, which may e.g. be performed in a manufacturing environment, e.g. during manufacturing. After the calibration, in some exemplary embodiments, the optical distribution network can e.g. be assumed to be stable.

In some exemplary embodiments, a procedure of measuring and calibrating the optical distribution network can e.g. be done by measuring individual absolute phases of the individual paths of the optical distribution network, e.g. one-by-one, and/or by measuring relative phases, e.g. with respect to a reference path (e.g., one selected optical path), e.g. for each optical network path. In some exemplary embodiments, in both cases, so determined phase values may e.g. be used to store e.g. resulting correction values, e.g. per optical sync path, e.g. organized in the form of a look-up-table, which correction values may e.g. subsequently be applied to the respective phase shifters of the individual optical distribution network paths.

In some exemplary embodiments, a phase of the radio frequency signal(s) provided by the resonant tunneling diode elements can be determined, e.g. measured.

In some exemplary embodiments, e.g. in case of that, e.g. contrary to an expectation, the phases in the optical distribution network show variations over time, e.g. after initial calibration, e.g. in the manufacturing environment, in some exemplary embodiments, such phase variations may e.g. be handled/considered by regular system calibration measurements (e.g., over-the-air calibration measurements with a reference calibration antenna or by multi-antenna array internal antenna coupling measurements).

In some exemplary embodiments, e.g. in cases where it cannot be distinguished between phase differences caused by an optical distribution network for providing the optical synchronization signal and e.g. differences caused by individual RTD elements and optionally a surrounding network (e.g. filter, antennas, etc.), one or more components, e.g. an overall system e.g. comprising the optical distribution network and one or more RF signal paths, e.g. TX paths, may be commonly, e.g. simultaneously, calibrated.

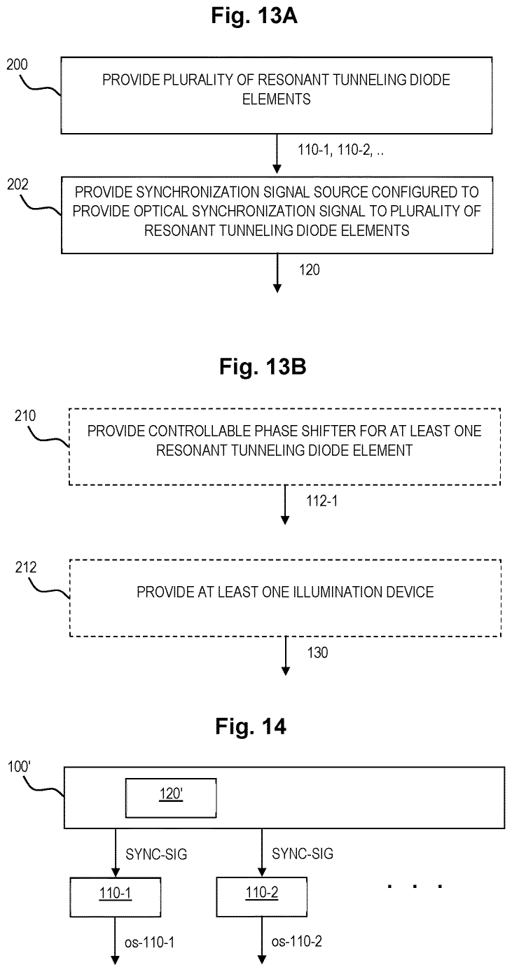

Further exemplary embodiments, FIG. 13A, relate to a method of manufacturing an apparatus 100 comprising a plurality of resonant tunneling diode, RTD, elements 110-1, 110-2, . . . (FIG. 1), comprising: providing 200 (FIG. 13A) the plurality of resonant tunneling diode, RTD, elements 110-1, 110-2, . . . , for example on a common carrier, providing 202 a synchronization signal source 120 configured to provide an optical synchronization signal SYNC-SIG to the plurality of resonant tunneling diode elements 110-1, 110-2, . . . .

In some exemplary embodiments, FIG. 13B, the method comprises at least one of: a) providing 210 a controllable phase shifter 112-1 (also see, for example, FIG. 5) configured to modify a phase of the optical synchronization signal SYNC-SIG for at least one resonant tunneling diode element of the plurality of resonant tunneling diode elements, providing 212 at least one illumination device 130 configured to provide the optical synchronization signal to at least one resonant tunneling diode element of the plurality of resonant tunneling diode elements.

Further exemplary embodiments, FIG. 14, relate to an apparatus 100′ comprising a plurality of resonant tunneling diode elements 110-1, 110-2, . . . and synchronization means 120′ configured to provide an optical synchronization signal SYNC-SIG to the plurality of resonant tunneling diode elements.

Further exemplary embodiments, FIG. 10, relate to an antenna system 1000 comprising one or more antenna elements 1010 and at least one apparatus 100 (FIG. 1) according to the embodiments.

In some exemplary embodiments, an optically synced RTD element array can e.g. be achieved by scaling/combining a larger number of the exemplary configuration of FIG. 5, also see FIGS. 9A, 9B.

Even though the example shown in FIGS. 9A, 9B comprises 25 RTD elements 110-1, . . . , 110-25, in some exemplary embodiments, RTD element arrays may be provided that may comprise a much larger number of RTD elements (e.g., having a larger array size), e.g. in order to achieve sufficient transmit power and thus e.g. link distance, e.g. for high frequency ranges e.g. in high mm-wave, sub-THz or THz frequency range.

In some exemplary embodiments, as e.g. already described above, each RTD element may comprise an “own” phase shifter, e.g. having an EC-material EM, e.g. enabling to dynamically compensate possible optical synchronization signal phase differences between different RTD elements, and, if applicable, in some exemplary embodiments, to consider/apply calibration phase weights and/or individual antenna beamforming weights.

While in some exemplary embodiments, each RTD element and each phase shifter may have a respective individual biasing or control signal, e.g. in order to individually control and/or configure an addressed RTD element, in some other exemplary embodiments, e.g. depending on a frequency range and/or to reduce complexity, possible sub-groups of RTD elements and phase shifters may be implemented with common control signals, e.g. biasing.

In some exemplary embodiments, a further implementation variant provides dividing an RTD element array (e.g., FIGS. 9A, 9B) into sub-arrays (not shown), which are e.g. independently operated regarding at least one of: a) optical synchronization signal(s), b) control signals, e.g. for phase shifter(s) and/or other components, e.g. of RTD elements.

While RF signal modulation is not explained in detail, in some exemplary embodiments, such RF signal modulation may e.g. be done by known methods like bias modulation of at least one RTD element or, e.g. under consideration of limited EC material response times—by an additional external modulation layer (not shown).

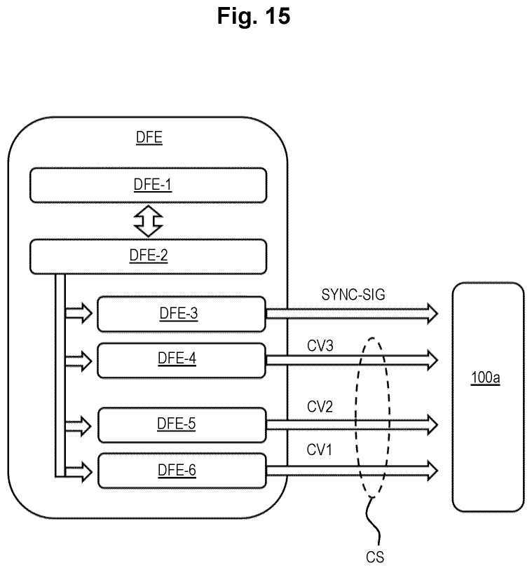

FIG. 15 schematically depicts an exemplary implementation of functional blocks associated with a digital frontend DFE (also see, for example, element A6 of FIGS. 10, 11, 12) and related interfaces according to exemplary embodiments, which may e.g. be used to, for example adequately, control and/or configure and/or operate an optically synchronized RTD element based array 100a according to exemplary embodiments.

Element DFE-1 symbolizes an exemplary beam control and/or beam steering, e.g. associated with an array or a sub-array of antenna elements, according to exemplary embodiments.

Element DFE-2 symbolizes a control and/or alignment of a, for example transmit (TX), center frequency and synchronization according to exemplary embodiments, which may e.g. be coordinated based on the beam control of block DFE-1.

Element DFE-3 symbolizes a control of the optical synchronization signal SYNC-SIG according to exemplary embodiments.

Element DFE-4 symbolizes a control of a local oscillator (LO) frequency, e.g. of an RTD-element based oscillator circuit, see, for example, FIG. 3B, and control signal, e.g. voltage, CV3 of FIG. 15.

Element DFE-5 symbolizes a control of an, e.g. individual, biasing for one or more RTD elements, see also the control signal, e.g. voltage, CV2.

Element DFE-6 symbolizes a control of, e.g. individual, phase shifters for one or more RTD elements, see also the control signal, e.g. voltage, CV1.

In some exemplary embodiments, the control signals CV1, CV2, CV3 form a control interface CS.

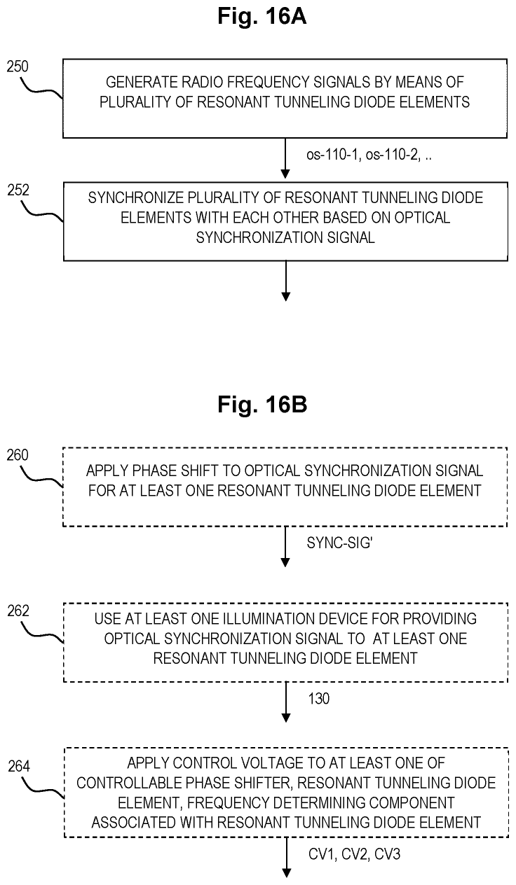

Further exemplary embodiments, FIG. 16A, relate to a method of operating an apparatus 100 (FIG. 1) comprising a plurality of resonant tunneling diode, RTD, elements 110-1, 110-2, . . . and a synchronization signal source 120 configured to provide an optical synchronization signal SYNC-SIG to the plurality of resonant tunneling diode elements, the method comprising: generating 250, by means of the plurality of resonant tunneling diode, RTD, elements, radio frequency signals os-110-1, os-110-2, . . . , synchronizing 252 the plurality of resonant tunneling diode, RTD, elements 110-1, 110-2, . . . with each other based on the optical synchronization signal SYNC-SIG.

In some exemplary embodiments, FIG. 16B, the method comprises at least one of: a) applying 260 a phase shift to the optical synchronization signal SYNC-SIG by means of a (e.g., at least one) controllable phase shifter 112-1, b) using 262 at least one illumination device 130 for providing the optical synchronization signal to at least one resonant tunneling diode element of the plurality of resonant tunneling diode elements, c) applying 264 a control signal, for example control voltage, CV1, CV2, CV3 to at least one of c1) a controllable phase shifter 112-1 (FIG. 5), c2) a resonant tunneling diode element 110-1, c3) a frequency determining component associated with the resonant tunneling diode element 110-1.

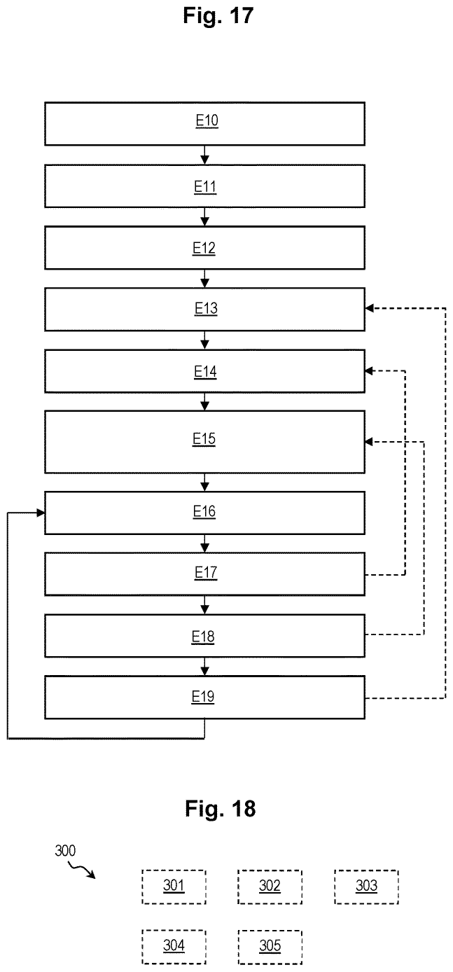

Further exemplary embodiments, FIG. 17, relate to exemplarily aspects of configuration and/or operation of an optically synchronized RTD element array according to some exemplary embodiments.

In the first steps of the method, the optically synchronized RTD element array is activated (see block E10) and configured, see block E11. If necessary and/or applicable, calibration and beamforming weights may considered. Afterwards, the RTD element array may e.g. starts with normal operation, e.g. with optional steps of re-calibration, update on beamforming phase weights and/or optical sync re-alignment if necessary/applicable. More specifically, element E12 symbolizes providing the optical synchronization signal, e.g. by activating the synchronization signal source 120 (FIG. 1). Element E13 symbolizes applying individual RTD element synchronization delay/phase compensation, e.g. by using the at least one controllable phase shifter 112-1. Element E14 symbolizes performing an optional (e.g., if applicable) RTD element array calibration and determination of calibration weights (e.g. characterizing at least one of a delay, phase or magnitude). Element E15 symbolizes an optional (e.g., if applicable) determination of common optical synchronization, calibration and beamforming delay and phase weights, e.g. for suitably controlling and/or setting a biasing of individual phase shifters, e.g. per individual RTD element. Element E16 symbolizes operating the RTD element array based on determined control settings. Element E17 symbolizes determining whether a re-calibration of the RTD element array is required. If so, the procedure continues with element E14. Element E18 symbolizes determining whether a new set of relevant beamforming weights (e.g. characterizing delays and/or phases) is available. If so, the procedure continues with Element E15. Element E19 symbolizes determining whether re-adjusting of the optical synchronization signal (e.g., related to accuracy, change of carrier frequency, restart) is required. If so, the procedures continues with element E13. Alternatively, in some exemplary embodiments, the procedure may also continue with element E10. Otherwise, the procedure continues with Element E16.

Further exemplary embodiments, FIG. 18, relate to a use 300 of the apparatus 100 according to the embodiments and/or of the method according to the embodiments for at least one of: a) synchronizing 301 the plurality of resonant tunneling diode elements 110-1, 110-2, . . . with each other, e.g. by injection locking using the optical synchronization signal SYNC-SIG, b) providing 302 multiple synchronized radio frequency, RF, signals os-110-1, os-110-2, . . . , c) combining 303, e.g. coherently combining, multiple synchronized radio frequency, RF, signals, d) providing 304 radio frequency signals in the THz and/or sub-THz range e.g. having a power level lower than 0.1 mW, or, for example, higher than 0.1 mW, e.g. for sub-THz systems, e) providing 305 an optically synchronized resonant tunneling diode-based array, e.g. for a radio device such as e.g. a transmitter and/or receiver and/or transceiver, e.g. comprising a multi-antenna system, f) synchronizing several, e.g. spatially distributed, radio devices, e.g. transceivers.

The principle according to the embodiments can e.g. be used for wireless communications systems, such as e.g. according to the sixth generation (6G) type, e.g. using multi-antenna systems, e.g. based on RTD element technologies.

The principle according to the embodiments can e.g. be applied to at least one of, but is not limited to, the following frequency ranges: a) sub-6 GHz, b) mm-wave, c) sub-THz, d) THZ.

The principle according to the embodiments can e.g. address issues related to synchronization of a large number (even up to thousands) of RTD elements, e.g. within an RTD element-based multi-antenna array, e.g. in order to enable beamforming operation.

1. An apparatus, comprising:
a plurality of resonant tunneling diode (RTD) elements; and
a synchronization signal source configured to provide an optical synchronization signal (SYNC-SIG) to the plurality of resonant tunneling diode elements.

2. The apparatus according to claim 1, wherein each of the plurality of resonant tunneling diode elements is configured to oscillate at a predetermined resonance frequency.

3. The apparatus according to claim 1, wherein the apparatus is configured to effect a phase synchronization of the plurality of resonant tunneling diode elements by injection locking of the plurality of resonant tunneling diode elements using the optical synchronization signal (SYNC-SIG).

4. The apparatus according to claim 1, wherein the plurality of resonant tunneling diode elements are configured in form of an array, wherein the array comprises at least one of: a) a one-dimensional array, b) a two-dimensional array, c) a three-dimensional array.

5. The apparatus according to claim 1, wherein the plurality of resonant tunneling diode elements comprises more than 64 resonant tunneling diode elements.

6. The apparatus according to claim 2, wherein a or the predetermined resonance frequency of the plurality of resonant tunneling diode elements is between 1 GHz and 100 THz.

7. The apparatus according to claim 1, wherein at least one resonant tunneling diode element of the plurality of resonant tunneling diode elements comprises a controllable phase shifter configured to modify a phase of the optical synchronization signal (SYNC-SIG).

8. The apparatus according to claim 7, wherein the controllable phase shifter comprises a material (EM) a permittivity of which can be controlled by applying a control signal (CS-112-1) to the material (EM).

9. The apparatus according to claim 7, wherein the apparatus is configured to modify the phase of the optical synchronization signal (SYNC-SIG) by the controllable phase shifter to perform at least one of: a) compensating a phase shift of the optical synchronization signal (SYNC-SIG) for the at least one resonant tunneling diode element, with respect to other resonant tunneling diode elements of the plurality of resonant tunneling diode elements, b) calibration, e.g. of individual signal transmission paths, e.g. for providing the optical synchronization signal (SYNC-SIG) to the at least one resonant tunneling diode element, c) beamforming, e.g. when providing output signals (os-110-1, os-110-2, . . . ) of the plurality of resonant tunneling diode elements to an antenna system (10; 1000) comprising one or more antenna elements (10′; 1010), d) providing a predetermined delay and/or phase to an output signal (os-110-1) of the at least one resonant tunneling diode.

10. The apparatus according to claim 1, wherein at least one resonant tunneling diode element of the plurality of resonant tunneling diode elements is disposed on a carrier element.

11. The apparatus according to claim 1, further comprising an illumination device configured to provide the optical synchronization signal (SYNC-SIG) to at least one resonant tunneling diode of the plurality of resonant tunneling diode elements.

12. The apparatus according to claim 11, wherein the illumination device comprises at least one optical element.

13. The apparatus according to claim 7, further comprising an illumination device configured to provide the optical synchronization signal (SYNC-SIG) to at least one resonant tunneling diode of the plurality of resonant tunneling diode elements, wherein the controllable phase shifter is disposed between at least one component of the illumination device and the at least one resonant tunneling diode element.

14. A method of manufacturing an apparatus comprising a plurality of resonant tunneling diode (RTD) elements, said method comprising:
providing the plurality of resonant tunneling diode (RTD) elements;
providing synchronization signal source configured to provide an optical synchronization signal (SYNC-SIG) to the plurality of resonant tunneling diode elements.

15. The method according to claim 14, further comprising at least one of:
a) providing a controllable phase shifter configured to modify a phase of the optical synchronization signal (SYNC-SIG) for at least one resonant tunneling diode element of the plurality of resonant tunneling diode elements, and
b) providing at least one illumination device configured to provide the optical synchronization signal (SYNC-SIG) to at least one resonant tunneling diode of the plurality of resonant tunneling diode elements.

16-20. (canceled)
